(19) United States
(12) Patent Application Publication
(10) Pub. No.: US 2025/0386515 A1
(43) Pub. Date: Dec. 18, 2025

(54) MEMORY DEVICE AND MANUFACTURING METHOD THEREOF

(71) Applicant: UNITED MICROELECTRONICS CORP., Hsin-Chu City (TW)

(72) Inventor: Ching-Hua Hsu, Kaohsiung City (TW)

(73) Assignee: UNITED MICROELECTRONICS CORP., Hsin-Chu City (TW)

(21) Appl. No.: 18/774,882

(22) Filed: Jul. 16, 2024

(30) Foreign Application Priority Data
Jun. 17, 2024 (TW) 113122245

(51) Int. Cl. H10B 61/00; G01R 33/09; H10N 50/01; H10N 50/10

(52) U.S. Cl. CPC H10B 61/22; G01R 33/098; H10N 50/01; H10N 50/10

(57) ABSTRACT

A memory device includes magnetic tunneling junction (MTJ) structures disposed above a substrate, top electrodes disposed above the substrate, a cap layer, a first dielectric layer, a sacrifice layer, and contact structures disposed above the substrate. Each top electrode is disposed on one of the MTJ structures. The cap layer is disposed conformally on the top electrodes and the MTJ structures. The first dielectric layer is disposed on the cap layer and located between the MTJ structures in a horizontal direction. The sacrifice layer is disposed on the cap layer and the first dielectric layer and is directly connected with the first dielectric layer. A bottom surface of the sacrifice layer is higher than a top surface of each top electrode in a vertical direction. Each contact structure is disposed on and connected with one of the top electrodes and penetrates through the sacrifice layer in the vertical direction.

### BACKGROUND OF THE INVENTION

### 1. Field of the Invention

The present invention relates to a memory device and a manufacturing method thereof, and more particularly, to a memory device including a magnetic tunnel junction structure and a manufacturing method thereof.

### 2. Description of the Prior Art

There are essentially two types of data memory devices used in electronic products, non-volatile and volatile memory devices. Magnetoresistive random access memory (MRAM) is a kind of non-volatile memory technology. Unlike current industry-standard memory devices, MRAM uses magnetism instead of electrical charges to store data. In general, MRAM cells include a data layer and a reference layer. The data layer is composed of a magnetic material and the magnetization of the data layer can be switched between two opposing states by an applied magnetic field for storing binary information. The reference layer can be composed of a magnetic material in which the magnetization is pinned. During the read operation, the resistance of the MRAM cell is different when the magnetization alignments of the data layer and the reference layer are the same or not, and the magnetization polarity of the data layer can be identified accordingly. The structure of MRAM devices will vary depending on the technology used to magnetize the data layer. In addition, the process of forming MRAM devices may be integrated in the back end of line (BEOL) process of the semiconductor manufacturing processes, and the integration with the BEOL process is influenced by the structural design of the MRAM devices, Therefore, how to improve the process integration of the MRAM devices through structural design and/or process design is an ongoing research direction for people in related fields.

### SUMMARY OF THE INVENTION

A memory device and a manufacturing method thereof are provided in the present invention. A sacrifice layer is formed on a cap layer and a first dielectric layer, and a contact structure located corresponding to a top electrode penetrates through the sacrifice layer for enhancing manufacturing yield and/or improving process integration of the memory device.

According to an embodiment of the present invention, a memory device is provided. The memory device includes magnetic tunneling junction (MTJ) structures, top electrodes, a cap layer, a first dielectric layer, a sacrifice layer, and contact structures. The MTJ structures, the top electrodes, and the contact structures are disposed above a substrate. Each of the top electrodes is disposed on one of the MTJ structures. The cap layer is disposed conformally on the top electrodes and the MTJ structures. The first dielectric layer is disposed on the cap layer and located between the MTJ structures in a horizontal direction. The sacrifice layer is disposed on the cap layer and the first dielectric layer. The sacrifice layer is directly connected with the first dielectric layer, and a bottom surface of the sacrifice layer is higher than a top surface of each of the top electrodes in a vertical direction. Each of the contact structures is disposed on and connected with one of the top electrodes, and each of the contact structures penetrates through the sacrifice layer in the vertical direction.

According to another embodiment of the present invention, a manufacturing method of a memory device is provided. The manufacturing method includes the following steps. Magnetic tunneling junction (MTJ) structures and top electrodes are formed above a substrate, and each of the top electrodes is located on one of the MTJ structures. A cap layer is formed conformally on the top electrodes and the MTJ structures. A first dielectric layer is formed on the cap layer, and the first dielectric layer is located between the MTJ structures in a horizontal direction. A sacrifice layer is formed on the cap layer and the first dielectric layer, and the sacrifice layer is directly connected with the first dielectric layer. The contact structures are formed above the substrate, each of the contact structures is located on and connected with one of the top electrodes, and each of the contact structures penetrates through the sacrifice layer in a vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a memory device according to an embodiment of the present invention.

FIGS. 2-11 are schematic drawings illustrating a manufacturing method of a memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is another cross-sectional schematic drawing illustrating the condition of FIG. 8, FIG. 10 is a schematic drawing in a step subsequent to FIG. 8, and FIG. 11 is another cross-sectional schematic drawing illustrating the condition of FIG. 10.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

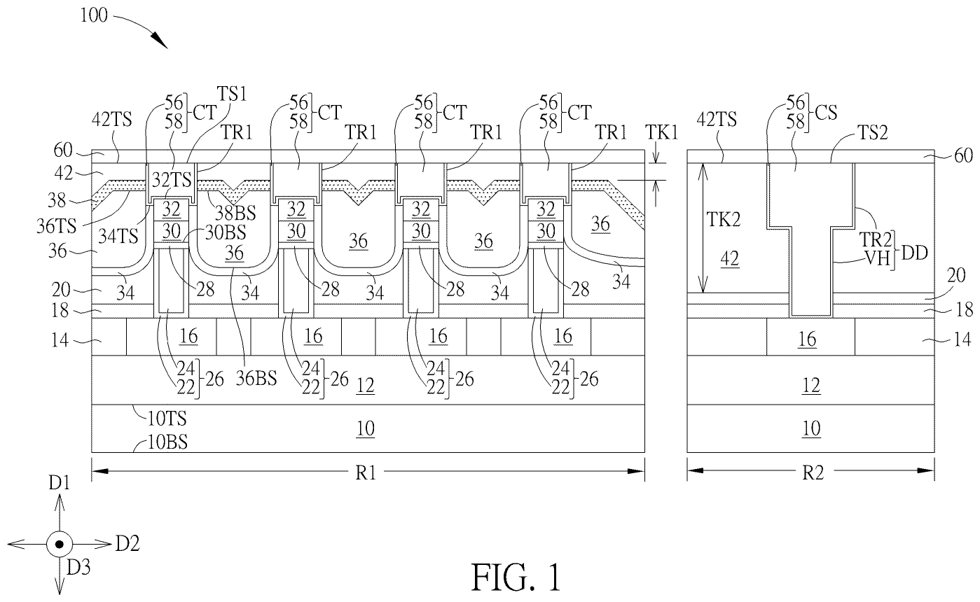

Please refer to FIG. 1. FIG. 1 is a schematic drawing illustrating a memory device 100 according to an embodiment of the present invention. As shown in FIG. 1, the memory device 100 includes a plurality of magnetic tunneling junction (MTJ) structures (such as MTJ structures 30), top electrodes 32, a cap layer 34, a first dielectric layer 36, a sacrifice layer 38, and a plurality of contact structures CT. The MTJ structures 30, the top electrodes 32, and the contact structures CT are disposed above a substrate 10. Each of the top electrodes 32 is disposed on one of the MTJ structures 30. The cap layer 34 is disposed conformally on the top electrodes 32 and the MTJ structures 30. The first dielectric layer 36 is disposed on the cap layer 34 and located between the MTJ structures 30 in a horizontal direction (such as a horizontal direction D2 and/or a horizontal direction D3). The sacrifice layer 38 is disposed on the cap layer 34 and the first dielectric layer 36. The sacrifice layer 38 is directly connected with the first dielectric layer 36, and a bottom surface 38BS of the sacrifice layer 38 is higher than a top surface 32TS of each of the top electrodes 32 in a vertical direction D1. Each of the contact structures CT is disposed on and connected with one of the top electrodes 32, and each of the contact structures CT penetrates through the sacrifice layer 38 in the vertical direction D1. The negative influence of the process of forming the contact structures CT on the top electrodes 32 and the MTJ structures 30 may be reduced and/or the process integration between the contact structures CT and other connection structures may be improved by disposing the sacrifice layer 38, and the purposes of process simplification and/or manufacturing yield enhancement may be achieved accordingly.

In some embodiments, the vertical direction D1 may be regarded as a thickness direction of the substrate 10. The substrate 10 may have a top surface 10TS and a bottom surface 10BS opposite to the top surface 10TS in the vertical direction D1, and the MTJ structures 30, the top electrodes 32, the cap layer 34, the first dielectric layer 36, the sacrifice layer 38, and the contact structures CT may be disposed at the side of the top surface 10TS. Horizontal directions substantially orthogonal to the vertical direction D1 (such as the horizontal direction D2 and the horizontal direction D3) may be substantially parallel with the top surface 10TS and/or the bottom surface 10BS of the substrate 10, but not limited thereto. In this description, a distance between the bottom surface 10BS of the substrate 10 and a relatively higher location and/or a relatively higher part in the vertical direction D1 may be greater than a distance between the bottom surface 10BS of the substrate 10 and a relatively lower location and/or a relatively lower part in the vertical direction D1. The bottom or a lower portion of each component may be closer to the bottom surface 10BS of the substrate 10 in the vertical direction D1 than the top or upper portion of this component. Another component disposed above a specific component may be regarded as being relatively far from the bottom surface 10BS of the substrate 10 in the vertical direction D1, and another component disposed under a specific component may be regarded as being relatively close to the bottom surface 10BS of the substrate 10 in the vertical direction D1, but not limited thereto. It is worth noting that, in this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include a condition that the certain component is sandwiched between the two other components in the specific direction.

In some embodiments, the substrate 10 may include a memory region R1 and a logic region R2, the MTJ structures 30, the top electrodes 32, the cap layer 34, the first dielectric layer 36, the sacrifice layer 38, and the contact structures CT described above may be disposed above the memory region R1, and the memory region R1 may include a magnetoresistive random access memory (MRAM) region, but not limited thereto. In some embodiments, the memory device 100 may further include a plurality of bottom electrodes 28, a dielectric layer 12, a dielectric layer 14, a plurality of connection structures 16, a stop layer 18, a dielectric layer 20, and a plurality of connection structures 26. Each of the bottom electrodes 28 and each of the connection structures 26 may be disposed under the corresponding MTJ structure 30, and the bottom electrode 28 may be sandwiched between the corresponding MTJ structure 30 and the corresponding connection structure 26 in the vertical direction D1. The dielectric layer 12 and the dielectric layer 14 may be disposed above the memory region R1 and the logic region R2, the dielectric layer 14 is disposed on the dielectric layer 12, and the connection structures 16 are disposed in the dielectric layer 14. The stop layer 18 may cover the connection structures 16 and the dielectric layer 14 located on the memory region R1 and the logic region R2, the dielectric layer 20 may be disposed on the stop layer 18 and located above the memory region R1 and the logic region R2, and the connection structures 26 may be disposed in the dielectric layer 20 and the stop layer 18 located above the memory region R1. In some embodiments, the connection structure 16 and the connection structure 26 may be regarded as a trench conductor and a via conductor, respectively, but not limited thereto. In addition, the dielectric layer 20 may be located between the connection structures 26 adjacent to each other in the horizontal direction, and the dielectric layer 20 located between the connection structures adjacent to each other may include a concave top surface because of the influence of related processes. The bottommost portion of this concave top surface may be lower than the bottom electrode 28 in the vertical direction D1 and higher than the bottom surface of the connection structure 20 in the vertical direction D1, and a thickness of the dielectric layer 20 located above the logic region R2 may be less than a thickness of the dielectric layer 20 located above the memory region R1. The cap layer 34 may be further formed on the dielectric layer 20 conformally, and the cap layer 34 may directly contact the dielectric layer 20 and the connection structures 26, but not limited thereto.

In some embodiments, the substrate 10 may include a semiconductor substrate or a non-semiconductor substrate. The semiconductor substrate may include a silicon substrate, a silicon germanium semiconductor substrate or a silicon-on-insulator (SOI) substrate, and the non-semiconductor substrate may include a glass substrate, a plastic substrate, or a ceramic substrate, but not limited thereto. For example, when the substrate 10 includes a semiconductor substrate, a plurality of field effect transistors (not illustrated), a dielectric layer covering the field effect transistors (such as the dielectric layer 12 and the dielectric layer 14), and the connection structures 16 electrically connected with the field effect transistors may be disposed on the semiconductor substrate according to some considerations, and the connection structure 26 electrically connected with the bottom electrode 28 may be electrically connected with specific transistor via the corresponding connection structure 16, but not limited thereto. In some embodiments, the MTJ structures 30 may include a free layer, a barrier layer, and a reference layer (not illustrated) stacked sequentially from bottom to top, a protection layer (not illustrated) may be disposed between the sidewall of the MTJ structure 30 and the cap layer 34, and the protection layer may be formed in the process of forming the MTJ structure 30 concurrently, but not limited thereto. In addition, the first dielectric layer 36 may be directly connected with the cap layer 34, a bottom surface 36BS of the first dielectric layer 36 may be lower than a bottom surface 30BS of each of the MTJ structures 30 in the vertical direction D1, and a top surface 36TS of the first dielectric layer 36 may be higher than the top surface 32TS of each of the top electrodes 32 in the vertical direction D1. The bottom surface 38BS of the sacrifice layer 38 may be directly connected with the top surface 36TS of the first dielectric layer 36, and the bottom surface 38BS may be higher than the top surface 32TS of each of the top electrodes 32 in the vertical direction D1. In some embodiments, each of the contact structures CT may directly contact the corresponding top electrode 32, a part of each of the contact structures CT may be lower than the top surface 32TS of the corresponding top electrode 32 in the vertical direction D1 and surround the top electrode in the horizontal direction, and a top surface 34TS of the cap layer 34 may be lower than the top surface 32TS of the top electrode 32 in the vertical direction D1.

In some embodiments, the memory device100 may further include a second dielectric layer 42, an interconnection structure CS, and a stop layer 60. The second dielectric layer 42 is disposed above the substrate, and the second dielectric layer 42 is partly disposed above the memory region R1 and partly disposed above the logic region R2. The sacrifice layer 38 may be sandwiched between the first dielectric layer 36 and the second dielectric layer 42 located above the memory region R1 in the vertical direction D1, and each of the contact structures CT may further penetrate through the second dielectric layer 42 located above the memory region R1 in the vertical direction D1. The interconnection structure CS is disposed above the logic region R2, and the interconnection structure CS penetrates through the second dielectric layer 42, the dielectric layer 20, and the stop layer 18 in the vertical direction D1 for contacting and being electrically connected with the corresponding connection structure 16. In addition, a part of the second dielectric layer 42 (such as the second dielectric layer 42 located above the memory region R1) may be disposed on and directly connected with the sacrifice layer 38, and another part of the second dielectric layer 42 (such as the second dielectric layer 42 located above the logic region R2) may be disposed on and directly connected with the dielectric layer 20. In some embodiments, a top surface TS2 of the interconnection structure CS, a top surface TS1 of each of the contact structures CT, and a top surface 42TS of the second dielectric layer 42 may be substantially coplanar, and the stop layer 60 may cover and directly contact the top surface TS2, the top surface TS1, and the top surface 42TS. In addition, a thickness TK2 of the second dielectric layer 42 disposed above the logic region R2 may be greater than a thickness TK1 of the second dielectric layer 42 disposed above the memory region R1, and the thickness TK1 may be regarded as the thickness minimum of the second dielectric layer 42 located above the memory region R1, but not limited thereto.

In some embodiments, a material composition of the first dielectric layer 36 is different from a material composition of the cap layer 34 and a material composition of the sacrifice layer 38 for providing desired etching selectivity in related processes. For example, the first dielectric layer 36 and the second dielectric layer 42 may include a low dielectric constant dielectric material (such as a dielectric material with dielectric constant lower than 2.9, but not limited thereto) or an ultra-low dielectric constant (ULK) dielectric material (such as a dielectric material with dielectric constant lower than 2.7, but not limited thereto), and the sacrifice layer 38 and the cap layer 34 may include an insulation material different from the material of the first dielectric layer 36 and having relatively low etching rate in the process of etching the first dielectric layer 36, such as silicon nitride or other suitable insulation materials. Additionally, in some embodiments, the material composition of the sacrifice layer 38 may be identical to the material composition of the cap layer 34 for simplifying related processes, such as integrating an etching step partially removing the sacrifice layer 38 and an etching step partially removing the cap layer 34, but not limited thereto. In other words, the material composition of the sacrifice layer 38 may be different from that of the cap layer 34 according to some design considerations. The top electrode 32 and the bottom electrode 28 may include tantalum, tantalum nitride, titanium, titanium nitride, platinum, copper, gold, aluminum, or other suitable electrically conductive materials. In addition, the free layer and the reference layer in the MTJ structure 30 may include ferromagnetic materials, such as iron, cobalt, nickel, cobalt-iron (CoFe), cobalt-iron-boron (CoFeB), or other suitable ferromagnetic materials. The barrier layer in the MTJ structure 30 may include insulation materials, such as magnesium oxide (MgO), aluminum oxide, or other suitable insulation materials.

In some embodiments, the dielectric layer 12, the dielectric layer 14, and the dielectric layer 20 may include oxide dielectric materials, low dielectric constant dielectric materials, or other suitable dielectric materials, and the dielectric constant of the first dielectric layer 36 and the dielectric constant of the second dielectric layer 42 may be lower than the dielectric constant of the dielectric layer 20, but not limited thereto. In some embodiments, each of the connection structures 16, each of the connection structures 26, each of the contact structures CT, and the interconnection structure CS may include a barrier layer and an electrically conductive material disposed on the barrier layer. The barrier layer may include titanium, titanium nitride, tantalum, tantalum nitride, or other suitable electrically conductive battier materials, and the electrically conductive material may include tungsten, copper, aluminum, titanium aluminide, cobalt tungsten phosphide, or other suitable electrically conductive materials with relatively low electrical resistivity. For example, each of the connection structure 26 may include a barrier layer 22 and an electrically conductive material 24 disposed on the barrier layer 22, each of the contact structures CT may include a barrier layer 56 and an electrically conductive material 58 disposed on the barrier layer 56, and interconnection structure CS may include the barrier layer 56 and the electrically conductive material 58 disposed on the barrier layer 56, but not limited thereto. In some embodiments, the interconnection structure CS may include a dual damascene structure or other suitable structures, and the interconnection structure CS may be partly disposed in a trench (such as a trench TR2) and partly disposed in a via hole VH located under the trench TR2, but not limited thereto. The stop layer 18 and the stop layer may include nitrogen doped carbide (NDC), silicon nitride, silicon carbon nitride (SiCN), or other suitable materials.

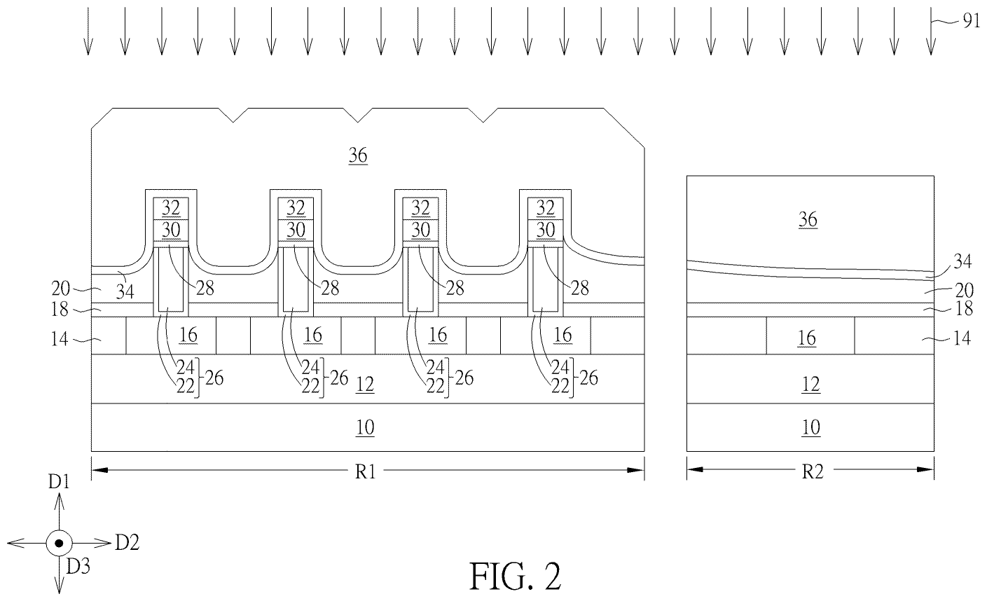

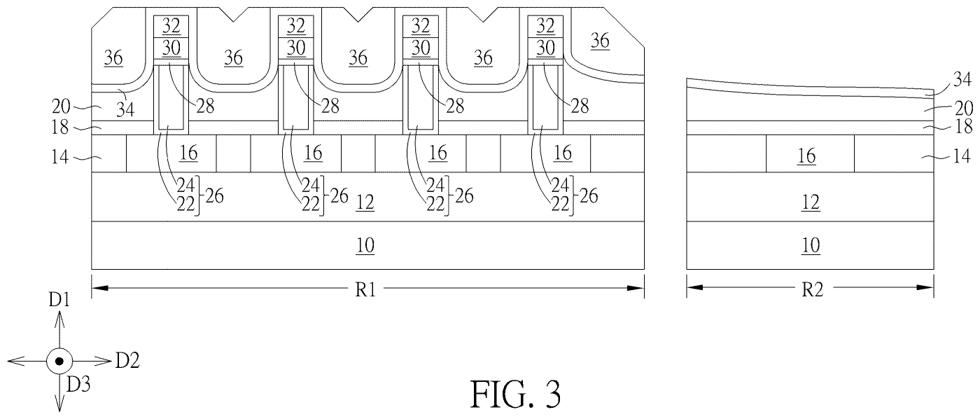

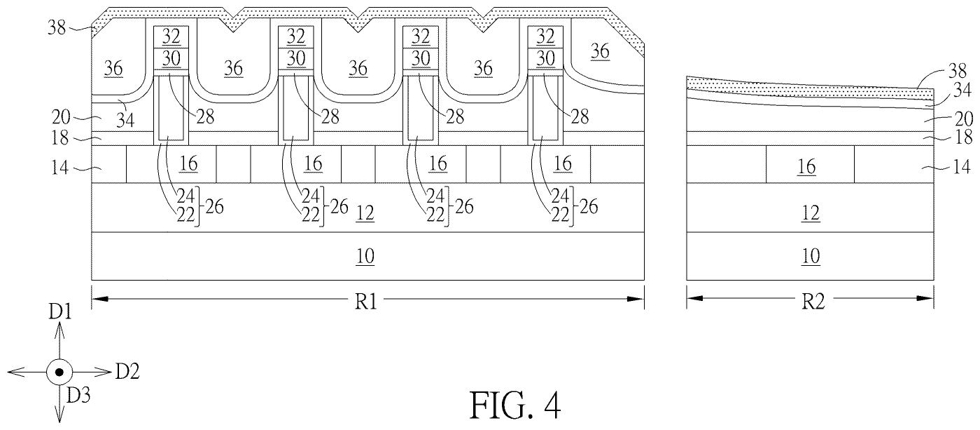

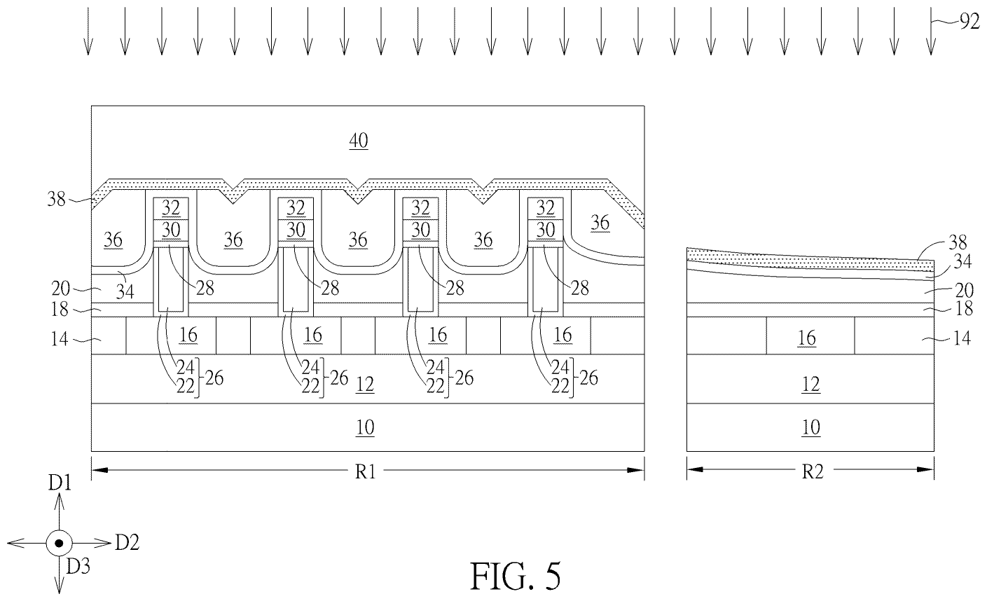

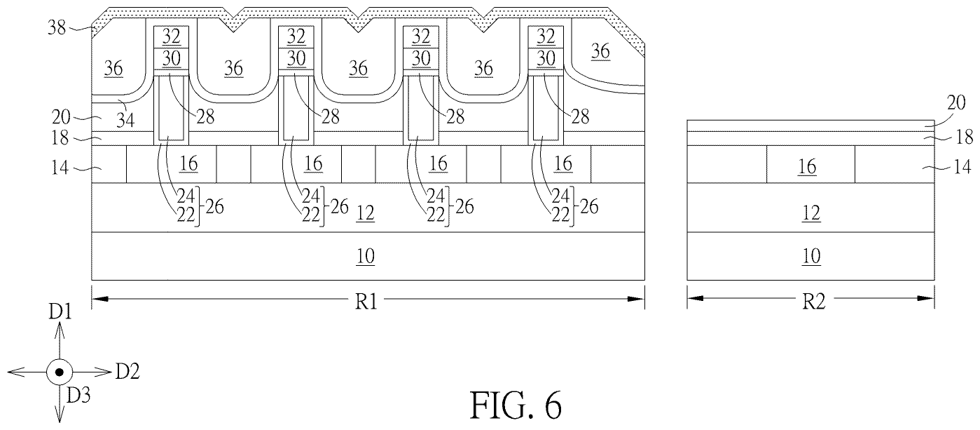

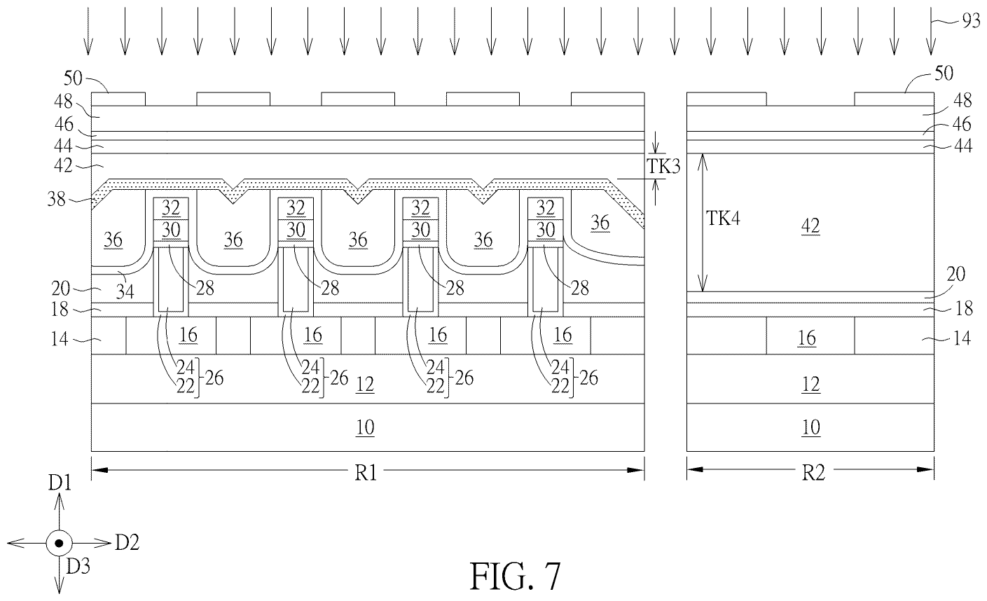

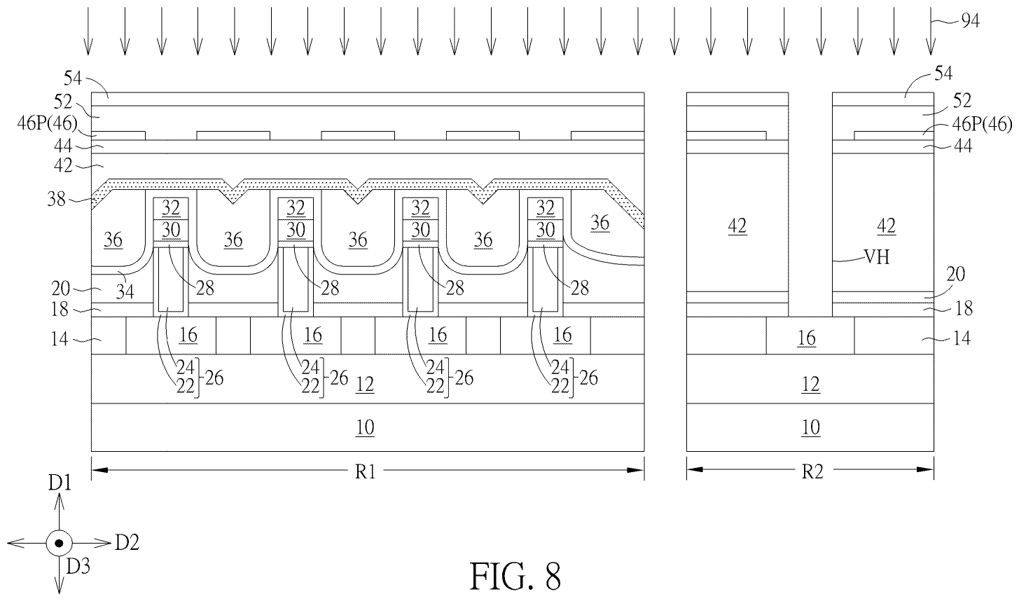

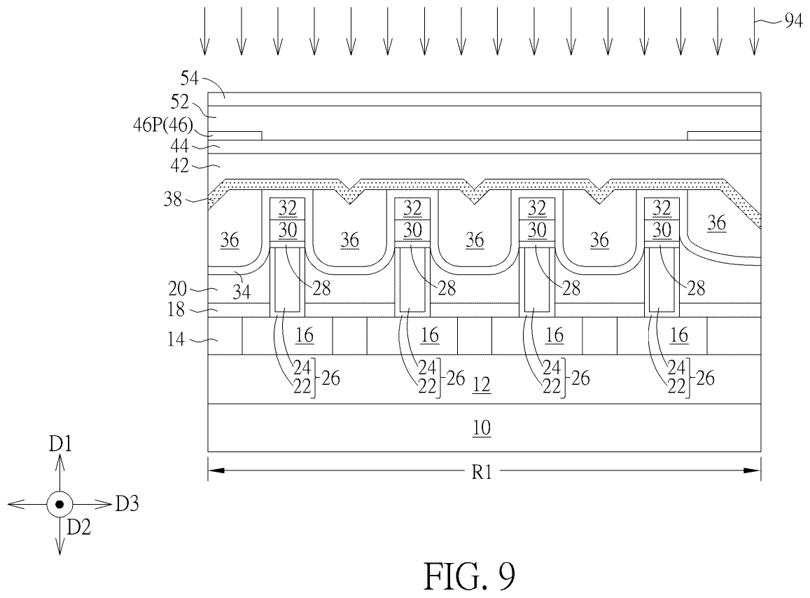

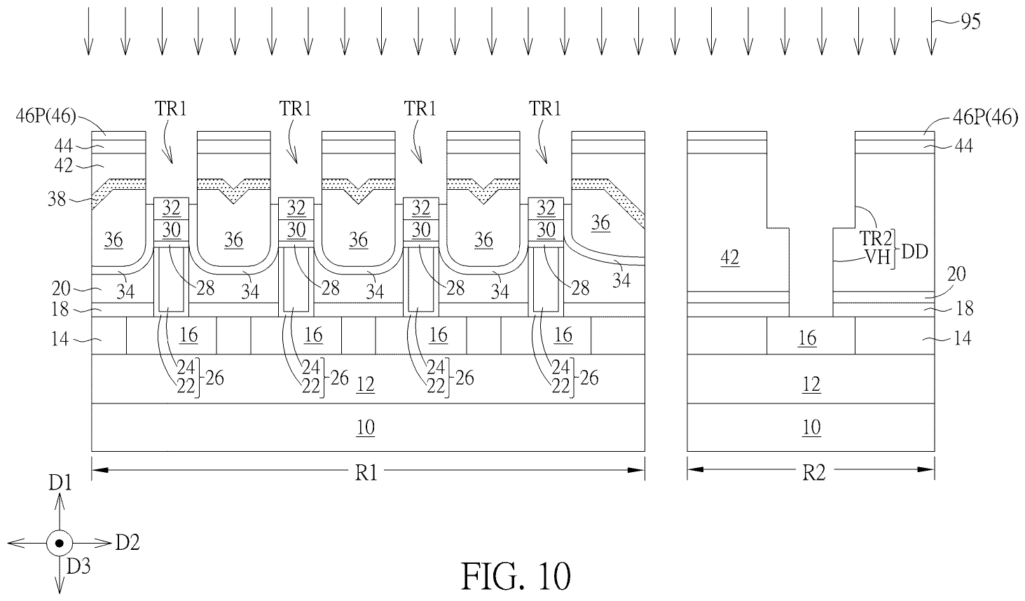

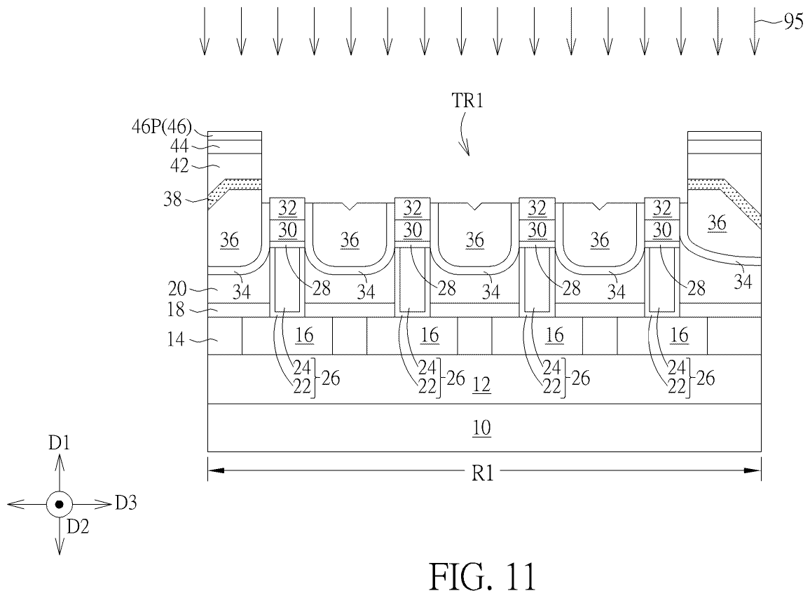

Please refer to FIGS. 1-11. FIGS. 2-11 are schematic drawings illustrating a manufacturing method of a memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is another cross-sectional schematic drawing illustrating the condition of FIG. 8, FIG. 10 is a schematic drawing in a step subsequent to FIG. 8, and FIG. 11 is another cross-sectional schematic drawing illustrating the condition of FIG. 10. In some embodiments, FIG. 1 may be regarded as a schematic drawing in a step subsequent to FIG. 10, but not limited thereto. In addition, the left portions of FIGS. 1-8 and 10 may be regarded as cross-sectional schematic drawings taken along a plane parallel with the vertical direction D1 and the horizontal direction D2, FIG. 9 and FIG. 11 may be regarded as cross-sectional schematic drawings taken along a plane parallel with the vertical direction D1 and the horizontal direction D3, and the horizontal direction D2 may be substantially orthogonal to the horizontal direction D3, but not limited thereto. As shown in FIG. 1, the manufacturing method in this embodiment includes the following steps. A plurality of magnetic tunneling junction (MTJ) structures (such as the MTJ structures 30) and a plurality of top electrodes 32 are formed above the substrate 10, and each of the top electrodes 32 is located on one of the MTJ structures 30. The cap layer 34 is formed conformally on the top electrodes 32 and the MTJ structures 30. The first dielectric layer 36 is formed on the cap layer 34, and the first dielectric layer 36 is located between the MTJ structures 30 in the horizontal direction (such as the horizontal direction D2 and/or the horizontal direction D3). The sacrifice layer 38 is formed on the cap layer 34 and the first dielectric layer 36, and the sacrifice layer 38 is directly connected with the first dielectric layer 36. The contact structures CT are formed above the substrate 10, each of the contact structures CT is located on and connected with one of the top electrodes 32, and each of the contact structures CT penetrates through the sacrifice layer 38 in the vertical direction D1.

Specifically, the manufacturing method in this embodiment may include but is not limited to the following steps. As shown in FIG. 2, active components (such as the transistors described above), passive components, or other required circuit structures may be formed on the substrate 10. The dielectric layer 12, the dielectric layer 24, the connection structures 16, the stop layer 18, and the dielectric layer 20 described above may be formed above the memory region R1 and the logic region R2 of the substrate 10, and the connection structures 26 may be formed above the memory region R1. Subsequently, the bottom electrodes 28, the MTJ structures 30, and the top electrodes 32 may be formed on the connection structures 26. In some embodiments, stacked material layers corresponding to the bottom electrode 28, the MTJ structure 30, and the top electrode 32 may be formed on the dielectric layer 20, and a patterning process may be performed to the stacked material layers for forming the top electrodes 32, the MTJ structures 30, and the bottom electrodes 28, but not limited thereto. The patterning process described above may include an ion beam etching (IBE) process or other suitable etching approaches, the dielectric layer 20 located between the connection structures 26 adjacent to each other may have a concave top surface because of the influence of the characteristics of the IBE process, and the bottommost portion of this top surface may be lower than the bottom electrode 28 and higher than the bottom surface of the connection structure 26 in the vertical direction D1. Subsequently, the cap layer 34 may be formed conformally on the dielectric layer 20, the bottom electrodes 28, the MTJ structures 30, and the top electrodes 32, and the first dielectric layer 36 may be formed on the cap layer 34. Therefore, the bottom electrodes 28, the MTJ structures 30, and the top electrodes 32 may be formed above the memory region R1, and the cap layer 34 and the first dielectric layer 36 may be partly formed above the memory region R1 and partly formed above the logic region R2. In some embodiments, the first dielectric layer 36 may include an oxide dielectric layer formed by an atomic layer deposition (ALD) process, and the top surface of the first dielectric layer 36 formed above the memory region R1 may be higher than the top surface of the first dielectric layer 36 formed above the logic region R2 in the vertical direction D1 because of the influence of the dielectric layer 20, the connection structures 26, the bottom electrodes 28, the MTJ structures 30, and the top electrodes 32 located above the memory region R1, but not limited thereto.

As shown in FIG. 2 and FIG. 3, after the step of forming the first dielectric layer 36, an etching back process 91 may be performed to the first dielectric layer 36 for removing the first dielectric layer 36 located above the logic region R2, the cap layer 34 located above the top electrodes 32 may be exposed after the etching back process 91, and the first dielectric layer 36 remains after the etching back process 91 may be located between the MTJ structures 30 adjacent to each other in the horizontal direction. Subsequently, as shown in FIG. 4, the sacrifice layer 38 may be formed, and the sacrifice layer 38 may be partly formed above the memory region R1 and partly formed above the logic region R2. The sacrifice layer 38 formed above the logic region R2 may be formed on and directly contact the cap layer 34, and the sacrifice layer 38 formed above the memory region R1 may be formed on and directly contact the first dielectric layer 36 and the cap layer 34. Therefore, a part of the sacrifice layer 38 and a part of the cap layer 34 may be located above the top electrodes 32 in the vertical direction D1. As shown in FIG. 5 and FIG. 6, the sacrifice layer 38 and the cap layer 34 formed above the logic region R2 may be removed. In some embodiments, a patterned mask layer 40 may be formed covering the sacrifice layer 38 formed above the memory region R1, and an etching process 92 using the patterned mask layer 40 as a mask may be performed for removing the sacrifice layer 38 and the cap layer 34 formed above the logic region R2. The patterned mask layer 40 may include a patterned photoresist layer or other suitable mask materials, and the patterned mask layer 40 may be removed after the etching process 92. The etching process 92 may include a dry etching process or other suitable etching approaches, the sacrifice layer 38 located above the logic region R2 and the cap layer 34 located above the logic region R2 may be completely removed by the etching process 92, and at least a part of the dielectric layer 20 located above the logic region R2 may be etched by the etching process 92. In some embodiments, the material composition of the sacrifice layer 38 may be identical to the material composition of the cap layer 34, and the sacrifice layer 38 formed above the logic region R2 and the cap layer 34 formed above the logic region R2 may be removed concurrently by the same process for process simplification, but not limited thereto.

In some embodiments, the dielectric layer 20 located above the logic region R2 may still cover the stop layer 18 located above the logic region R2 after the etching process 92, and the dielectric layer 20 located above the logic region R2 may be thinned by the etching process 92. Therefore, the top surface of the dielectric layer 20 located above the logic region R2 may be lower than the top surface of the dielectric layer 20 located above the memory region R1 after the etching process 92. Subsequently, as shown in FIGS. 5-7, the second dielectric layer 42 may be formed after the step of removing the sacrifice layer 38 and the cap layer 34 formed above the logic region R2, and the second dielectric layer 42 may be partly formed above the memory region R1 and partly formed above the logic region R2. In some embodiments, a dielectric material may be formed above the substrate 10, and a planarization process (such as a chemical mechanical polishing process, but not limited thereto) may be performed to the dielectric material for forming the second dielectric layer 42. Because of the influence of the difference between the condition above the memory region R1 and the condition above the logic region R2, a thickness TK4 of the second dielectric layer 42 formed above the logic region may be greater than a thickness TK3 of the second dielectric layer 42 formed above the memory region R1, and the thickness TK3 may be regarded as the thickness minimum of the second dielectric layer 42 formed above the memory region R1, but not limited thereto. In addition, a part of the second dielectric layer 42 may be formed on the sacrifice layer 38, and the sacrifice layer 38 may be sandwiched between the first dielectric layer 36 and the second dielectric layer 42 in the vertical direction D1.

As shown in FIGS. 7-9, after the second dielectric layer 42 is formed, a mask layer 44, a mask layer 46, an anti-reflection layer 48, and a patterned mask layer 50 may be sequentially formed on the second dielectric layer 42, and an etching process 93 using the patterned mask layer 50 as a mask may be performed to the mask layer 46 for forming a patterned mask layer 46P. After the patterned mask layer 46P is formed, the anti-reflection layer 48 and the patterned mask layer 50 may be removed, an anti-reflection layer 52 may be formed on the mask layer 44 and the patterned mask layer 46P, and a patterned mask layer 54 may be formed on the anti-reflection layer 52. Subsequently, an etching process 94 using the patterned mask layer 54 as a mask may be performed for forming the via hole VH penetrating through the anti-reflection layer 52, the mask layer 44, the second dielectric layer 42, the dielectric layer 20, and the stop layer 18 in the vertical direction D1 on the logic region R2. After the via hole VH is formed, the patterned mask layer 54 and the anti-reflection layer 52 may be removed, and an etching process 95 using the patterned mask layer 46P as a mask may be performed for forming a plurality of first trenches (such as trenches TR1) above the memory region R1 and a second trench (such as the trench TR2) above the logic region R2. In some embodiments, the patterned mask layer 50 and the patterned mask layer 54 may include patterned photoresist layers or other suitable mask materials, the mask layer 44 and the mask layer 46 may include a hard mask material (such as a nitride mask material, a metal mask material, and so forth) different from photoresist, and the material composition of the mask layer 44 may be different from the material composition of the mask layer 46 for providing desired etching selectivity, but not limited thereto. The trench TR2 may penetrate through a portion of the second dielectric layer 42 for being connected with the via hole VH and constituting a dual damascene opening DD with the via hole VH, and each of the trenches TRI may penetrate through the second dielectric layer 42, the sacrifice layer 38, and the cap layer 34 in the vertical direction D1 for exposing the corresponding top electrode 32. In other words, the dual damascene opening DD may include the trench TR2 and the via hole VH located under the trench TR2 and directly connected with the trench TR2, and the dual damascene opening DD may be formed above the logic region R2 and the dual damascene opening DD may penetrate through the second dielectric layer 42, the dielectric layer 20, and the stop layer 18 in the vertical direction D1 for exposing a part of the corresponding connection structure 16.

As shown in FIGS. 8-10, before the trench TR1 is formed, a part of the sacrifice layer 38 and a part of the cap layer 34 may be located above each of the top electrodes 32 in the vertical direction D1, the sacrifice layer 38 may directly contact the top surface of the cap layer 34, and the trenches TR1 may be formed by removing the second dielectric layer 42, the sacrifice layer 38, and the cap layer 34 located above the top electrodes 32 in the etching process 95. In some embodiments, the trenches TRI and the trench TR2 may be formed concurrently by the same process (such as the etching process 95), and a depth of the trench TR2 in the vertical direction D1 may be greater than a depth of each of the trenches TRI in the vertical direction D1 (the bottom of the trench TR2 may be lower than the bottom of each of the trenches TRI in the vertical direction D1, for instance). It is worth noting that, the etching rate of the sacrifice layer 38 and the etching rate of the cap layer 34 in the etching process 95 may be lower than the etching rate of the second dielectric layer 42 in the etching process 95, and the sacrifice layer 38 may be used to reduce the negative influence of the etching process 95 on the top electrodes 32 and/or the MTJ structures 30 accordingly, especially when the trench TR2 is relatively deep and the required etching strength of the etching process 95 is relatively high and/or the required etching time of the etching process 95 is relatively long accordingly. Therefore, the sacrifice layer 38 may be used to improve manufacturing yield and contribute to the effect of forming the trenches TRI and the trench TR2 by the same process, and the purposes of improving process integration and/or simplifying related processes may be achieved.

Subsequently, as shown in FIG. 10 and FIG. 1, a conductive material (such as the electrically conductive material 58 and the barrier layer 56) may be formed in the first trenches TRI and the dual damascene opening DD so as to form the contact structures CT above the memory region R1 and the interconnection structure CS above the logic region R2. In some embodiments, the electrically conductive material 58 and the barrier layer 56 may be partly formed in the trenches TRI and the dual damascene opening DD and partly formed outside the trenches TRI and the dual damascene opening DD, and a planarization process (such as a chemical mechanical polishing process) may be performed for removing the electrically conductive material 58 and the barrier layer 56 located outside the trenches TRI and the dual damascene opening DD and forming the contact structures CT and the interconnection structure CS accordingly. In some embodiments, the patterned mask layer 46P, the mask layer 44, and a part of the second dielectric layer 42 may be removed by the above-mentioned planarization process configured to form the contact structures CT and the interconnection structure CS, and the thickness of the second dielectric layer 42 after the planarization process may be less than the thickness of the second dielectric layer 42 before the planarization process accordingly, but not limited thereto. In some embodiments, the planarization process described above may stop on the second dielectric layer 42 without removing a part of the second dielectric layer substantially. In addition, after the planarization process, the stop layer 60 may be formed covering the top surface TS2 of the interconnection structure CS, the top surface TS1 of each of the contact structures CT, and the top surface 42TS of the second dielectric layer 42 for forming the memory device 100 illustrated in FIG. 1.

As shown in FIG. 1 and FIGS. 7-11, the contact structures CT and the interconnection structure CS may be formed concurrently by the same process, and the trenches TR1 corresponding to the contact structures CT and the trench TR2 corresponding to the interconnection structure CS may be formed concurrently by the same process for process integration and process simplification. Additionally, before the contact structures CT and the interconnection structure CS are formed, the sacrifice layer 38 and the cap layer 34 formed above the logic region R2 may be removed and the second dielectric layer 42 may be formed. Therefore, the dual damascene opening DD corresponding to the interconnection structure CS does not have to penetrate through the sacrifice layer 38 and the cap layer 34, and it is easier to form the deeper trench TR2 because the material of the second dielectric layer 42 may be etched more efficiently, but not limited thereto. It is worth noting that the method of forming the contact structures CT and the interconnection structure CS in the present invention may include but is not limited to the steps illustrated in FIGS. 7-11 described above, and the contact structures CT and the interconnection structure CS shown in FIG. 1 may also be formed by other suitable approaches according to some design considerations.

To summarize the above descriptions, in the memory device and the manufacturing method thereof according to the present invention, the sacrifice layer may be disposed on the cap layer and the first dielectric layer, and the contact structure corresponding to the top electrode may penetrate through the sacrifice layer for reducing the negative influence of the process of forming the contact structure on the top electrode and the MTJ structure and/or improving the process integration between the contact structure and other connection structures. The purposes of process simplification and/or manufacturing yield enhancement may be achieved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device, comprising:
magnetic tunneling junction (MTJ) structures disposed above a substrate;
top electrodes disposed above the substrate, wherein each of the top electrodes is disposed on one of the MTJ structures;
a cap layer disposed conformally on the top electrodes and the MTJ structures;
a first dielectric layer disposed on the cap layer and located between the MTJ structures in a horizontal direction;
a sacrifice layer disposed on the cap layer and the first dielectric layer, wherein the sacrifice layer is directly connected with the first dielectric layer, and a bottom surface of the sacrifice layer is higher than a top surface of each of the top electrodes in a vertical direction; and
contact structures disposed above the substrate, wherein each of the contact structures is disposed on and connected with one of the top electrodes, and each of the contact structures penetrates through the sacrifice layer in the vertical direction.

2. The memory device according to claim 1, wherein a material composition of the first dielectric layer is different from a material composition of the cap layer and a material composition of the sacrifice layer.

3. The memory device according to claim 1, wherein a material composition of the sacrifice layer is identical to a material composition of the cap layer.

4. The memory device according to claim 1, wherein a top surface of the first dielectric layer is higher than the top surface of each of the top electrodes, and a bottom surface of the first dielectric layer is lower than a bottom surface of each of the MTJ structures.

5. The memory device according to claim 1, further comprising:
a second dielectric layer disposed above the substrate, wherein a part of the second dielectric layer is disposed on the sacrifice layer, the sacrifice layer is sandwiched between the first dielectric layer and the second dielectric layer in the vertical direction, and the each of the contact structures further penetrates through the second dielectric layer in the vertical direction.

6. The memory device according to claim 5, wherein the second dielectric layer is directly connected with the sacrifice layer.

7. The memory device according to claim 5, wherein the substrate comprises a memory region and a logic region, the MTJ structures, the top electrodes, the first dielectric layer, and the contact structures are disposed above the memory region, and the second dielectric layer is partly disposed above the memory region and partly disposed above the logic region.

8. The memory device according to claim 7, wherein a thickness of the second dielectric layer disposed above the logic region is greater than a thickness of the second dielectric layer disposed above the memory region.

9. The memory device according to claim 7, further comprising:
an interconnection structure disposed above the logic region, wherein the interconnection structure penetrates through the second dielectric layer in the vertical direction, and a top surface of the interconnection structure, a top surface of each of the contact structures, and a top surface of the second dielectric layer are coplanar.

10. A manufacturing method of a memory device, comprising:
forming magnetic tunneling junction (MTJ) structures above a substrate;
forming top electrodes above the substrate, wherein each of the top electrodes is located on one of the MTJ structures;
forming a cap layer conformally on the top electrodes and the MTJ structures;
forming a first dielectric layer on the cap layer, wherein the first dielectric layer is located between the MTJ structures in a horizontal direction;
forming a sacrifice layer on the cap layer and the first dielectric layer, wherein the sacrifice layer is directly connected with the first dielectric layer; and
forming contact structures above the substrate, wherein each of the contact structures is located on and connected with one of the top electrodes, and each of the contact structures penetrates through the sacrifice layer in a vertical direction.

11. The manufacturing method of the memory device according to claim 10, wherein the substrate comprises a memory region and a logic region, the MTJ structures, the top electrodes, and the first dielectric layer are formed above the memory region, the sacrifice layer is partly formed above the memory region and partly formed above the logic region, and the manufacturing method further comprises:
removing the sacrifice layer formed above the logic region before the contact structures are formed.

12. The manufacturing method of the memory device according to claim 11, wherein the cap layer is partly formed above the memory region and partly formed above the logic region, and the manufacturing method further comprises:
removing the cap layer formed above the logic region before the contact structures are formed, wherein the cap layer formed above the logic region and the sacrifice layer formed above the logic region are removed by the same process.

13. The manufacturing method of the memory device according to claim 11, further comprising:
forming a second dielectric layer above the substrate before the contact structures are formed, wherein a part of the second dielectric layer is formed on the sacrifice layer, the sacrifice layer is sandwiched between the first dielectric layer and the second dielectric layer in the vertical direction, and the each of the contact structures further penetrates through the second dielectric layer in the vertical direction.

14. The manufacturing method of the memory device according to claim 13, wherein the second dielectric layer is formed after the sacrifice layer formed above the logic region is removed, and the second dielectric layer is partly formed above the memory region and partly formed above the logic region, wherein a thickness of the second dielectric layer formed above the logic region is greater than a thickness of the second dielectric layer formed above the memory region.

15. The manufacturing method of the memory device according to claim 14, further comprising:
forming an interconnection structure above the logic region, wherein the interconnection structure penetrates through the second dielectric layer in the vertical direction, and the contact structures and the interconnection structure are formed by the same process.

16. The manufacturing method of the memory device according to claim 15, wherein a method of forming the contact structures and the interconnection structure comprises:
forming first trenches above the memory region, wherein each of the first trenches penetrates through the second dielectric layer, the sacrifice layer, and the cap layer in the vertical direction;
forming a dual damascene opening above the logic region, wherein the dual damascene opening penetrates through the second dielectric layer in the vertical direction; and
forming a conductive material in the first trenches and the dual damascene opening.

17. The manufacturing method of the memory device according to claim 16, wherein the dual damascene opening comprises:
a second trench; and
a via hole located under the second trench, wherein the first trenches and the second trench are formed concurrently by the same process.

18. The manufacturing method of the memory device according to claim 16, wherein a part of the sacrifice layer and a part of the cap layer are located above each of the top electrodes in the vertical direction before the first trenches are formed.

19. The manufacturing method of the memory device according to claim 10, wherein a material composition of the first dielectric layer is different from a material composition of the cap layer and a material composition of the sacrifice layer.

20. The manufacturing method of the memory device according to claim 10, wherein a material composition of the sacrifice layer is identical to a material composition of the cap layer.
